(19) United States
(12) Patent Application Publication
(10) Pub. No.: US 2010/0036624 A1
(43) Pub. Date: Feb. 11, 2010

(54) STRESS CONDITION LOGGING IN UTILITY METER

(75) Inventors: Warren T. Martin, Lafayette, IN (US); John T. Voisine, Lafayette, IN (US)

Correspondence Address: MAGINOT, MOORE & BECK, LLP;CHASE TOWER, 111 MONUMENT CIRCLE, SUITE 3250, INDIANAPOLIS, IN, 46204, US

(73) Assignee: LANDIS+GYR, INC., Lafayette, IN (US)

(21) Appl. No.: 12/537,885

(22) Filed: Aug. 7, 2009

Related U.S. Application Data
(60) Provisional application No. 61/188,228, filed on Aug. 7, 2008.
(60) Provisional application No. 61/188,247, filed on Aug. 7, 2008.

(51) Int. Cl. G01R 21/00; G01R 11/32; G06F 19/00

(52) U.S. Cl. 702/61; 324/142

(57) ABSTRACT

An arrangement includes a utility meter housing that contains or supports a first sensor, a second sensor, and a processing circuit. The first sensor is configured to measure a first parameter, the first parameter relating to an environmental condition within the meter housing. The second sensor is configured to measure a second parameter. The processing circuit is operably connected to the first sensor and to the second sensor, and is configured to record information relating to one or more events, each event corresponding to a detection of an out of range condition by each of the first sensor and the second sensor.

This application claims the benefit of U.S. Provisional Patent Application Ser. No. 61/188,228 filed Aug. 7, 2008, and U.S. Provisional Patent Application Ser. No. 61/188,247, filed Aug. 7, 2009, both of which are incorporated herein by reference.

### FIELD OF THE INVENTION

This invention relates generally to electricity meters.

### BACKGROUND OF THE INVENTION

Electricity meters are devices that measure and/or meter aspects of electricity provided to a load. The load may be a residence, business, or even part of a larger electricity distribution system. Electricity meters are often subjected to a wide range of environmental and electrical conditions. Electricity meters are typically designed to withstand extremes in weather, as well as some degree of voltage and current swings.

However, there are conditions that can degrade the condition of a meter, or contribute to the failure of a meter. When a meter fails, considerable expense is incurred to repair and/or replace the meter. Furthermore, meter failure can result in loss of electrical service to the load. Finally, even if meter failure does not result in the loss of electrical service, it results in loss of revenue due to the energy supplier due to the inability to measure consumption.

As a consequence, there is always a need to reduce the number of meter failures, or at least the cost associated with meter failures.

### SUMMARY OF THE INVENTION

At least some embodiments of the present invention address the above described need, as well as others, by providing a stress condition logging arrangement in a utility meter. The stress condition logging can provide information about the frequency and/or severity of conditions that the meter is exposed to. Such information may be used to help predict the failure of components, or at least identify where conditions of the meter are contributing to failure. Such conditions may be addressed to potentially reduce the number of failures.

In a first embodiment, an arrangement includes a utility meter housing that contains or supports a first sensor, a second sensor, and a processing circuit. The first sensor is configured to measure a first parameter, the first parameter relating to an environmental condition within the meter housing. The second sensor is configured to measure a second parameter. The processing circuit is operably connected to the first sensor and to the second sensor, and is configured to record information relating to one or more events, each event corresponding to a detection of an out of range condition by each of the first sensor and the second sensor.

In a second embodiment, an arrangement includes a utility meter housing that supports or contains a voltage sensor, a current sensor, a first sensor, a second sensor, and a processing circuit. The first sensor is configured to measure a first parameter, the first parameter relating to a first condition within the meter housing. The second sensor is configured to measure a second parameter relating to a second condition within the meter housing, wherein the second condition is distinct from the first condition. The processing circuit is operably connected to the first sensor and to the second sensor, and is configured to record information relating to one or more events, each event corresponding to a detection of an out of range condition by each of the first sensor and the second sensor.

The recorded information, which may suitably constitute a stress condition log, can identify any condition that stresses the device beyond design limits. This information could be useful for such items as troubleshooting device failures, determining if a product repair should be covered by warranty, determining if a failure type is to be included in a reliability calculation, conducting a performance analysis, evaluating adequacy of design, refinement of design rules or design specifications, etc.

The above described features and advantages, as well as others, will become more readily apparent to those of ordinary skill in the art by reference to the following detailed description and accompanying drawings.

### BRIEF DESCRIPTION OF THE DRAWINGS

FIG. 1 shows a schematic block diagram of an exemplary meter that incorporates one or more stress condition detection functions, as well as logging of any detected stress conditions;

FIG. 2 shows an exemplary set of operations that are performed by a processing circuit of the meter of FIG. 1;

FIG. 3 shows an exemplary set of operations that are performed by a processing circuit of the meter of FIG. 1 to detect sustained over-voltage or over-current conditions;

FIG. 4 shows an exemplary set of operations that are performed by a processing circuit of the meter of FIG. 1 to process information from condition sensors;

FIG. 5 shows an alternative exemplary set of operations that are performed by a processing circuit of the meter of FIG. 1 to process information from condition sensors;

FIG. 6 shows a schematic diagram of an arrangement for detecting contaminants in accordance with one embodiment of the invention.

### DETAILED DESCRIPTION

As will be discussed below, one or more meters in an area are configured to detect and/or log or store stress conditions, wherein the stress condition does itself necessarily amount to a meter malfunction.

The overstress condition could include, but not be limited to, the following:

1. Sustained over voltage 60 hertz condition

2. Surge or spike over voltage condition

3. Sustained over current 60 hertz condition

4. Surge or spike over current condition

5. Temperature outside of specified limits

6. Current Coil temperature rise outside of limits

7. Excessive rate of change of temperature (Temperature Shock)

8. Excessive humidity

9. Presence of moisture

10. Excessive conducted or radiated electromagnetic fields

11. Excessive DC magnetic fields

12. Excessive power line frequency magnetic fields

13. Excessive electric fields

14. Excessive mechanical shock or vibration

15. Power line frequency outside of limits

16. Excessive electrostatic discharges

17. Presence of contaminants

18. Excessive ultraviolet radiation

19. Excessive number of operations of a switch

20. Opening of a switch under conditions of high current

21. Repeated power failures

For example detection of an over voltage condition in a device that employs an analog to digital converter could be accomplished by identifying and logging an event anytime the converter output exceeds a threshold or the output is found to be in a limit condition such as when the digital output is at the maximum possible digital value.

When the metering device is part of a communication network the system may provide for automatically communicating stress information to a central location. Thus, the central location may obtain logged/detected stress conditions from a plurality of meters in a geographical area.

Overstress information collected on a large population of devices may be used for statistical estimations of reliability or failure rates on a real time basis, etc. If different populations have unique design characteristics, accounting for differences in stress conditions may be useful in correlating performance to design characteristics. For example if one population of meters performs better compared to a second population of meters, erroneous conclusions could be made if the population performing poorer experienced a significantly greater number of overstress events compared to the first.

Additionally stress information from sub-populations in different areas can help to identify power quality issues that are unique to the area and identify where infrastructure improvements are needed in the utility distribution system.

Another possible use of data reported up through a network would be for different types of data to be reported to different end locations. For example typical billing information could be reported to the location responsible for compiling and reporting billing data at an electric utility. In contrast, information on overstress events could be automatically reported to the manufacturer of the end point device and not the electric utility at all. This is similar to when a computer program sends data over the internet back to the developer of the program when the program crashes, etc.

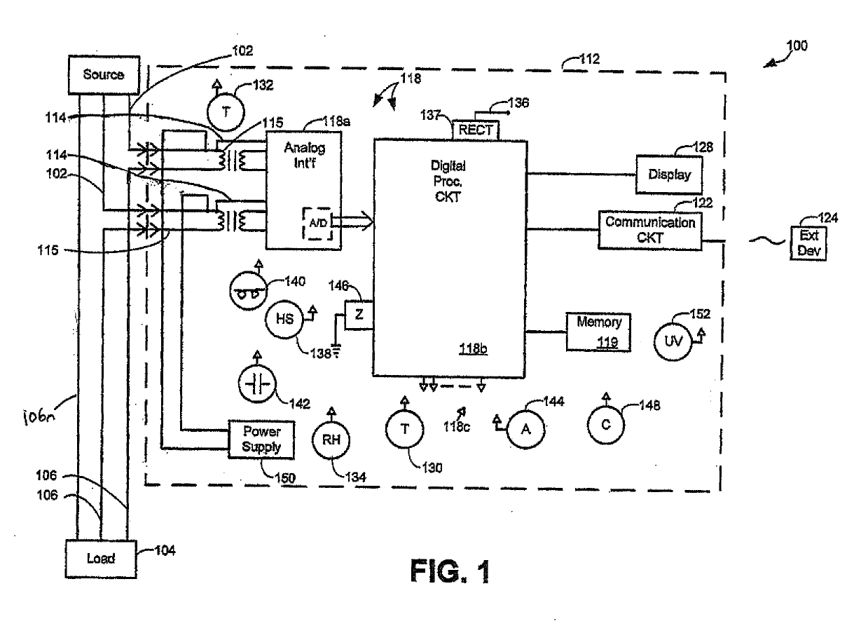

Referring now to the drawings, and more particularly to FIG. 1, a diagram of an exemplary electrical utility meter 100 constructed according to a first embodiment of the present invention is shown. As shown in FIG. 1, the meter 100 includes a housing 112 in which are disposed first and second current coils 115, first and second current measurement devices 116, voltage measurement devices 114, a processing circuit 118, a memory 119, a communication circuit 122, a display 128, and a power supply 150. The meter 100 also includes, disposed within the housing 112, a plurality of sensors 130, 132, 134, 136, 138, 140, 142, 144, 146, 148 and 152.

As shown in FIG. 1, the meter 100 is operably coupled to utility power lines 102 via first ends of each of the first and second current coils 115. The utility power lines 102 are connected to a source of electricity, such as a utility power transmission and distribution system, not shown. A load 104 (typically a consumer of electrical power) is connected to the power lines 102 through two feeder lines 106 and a neutral line 106n. The meter 100 is operably coupled to the feeder lines 106 via second ends of each of the first and second current coils 115.

Because the first and second current coils 115 are connected in the path between the power lines 102 and the feeder lines 106, the first and second current coils 115 provide access, within the meter 100, to the electricity delivered to the load 104. As will be discussed, other circuitry within the meter 100 is operably connected to the current coils 115 to detect the delivered electricity and, among other things, generate metering information representative of a quantity of electrical energy delivered to the load 104.

A housing 112 is disposed over the meter 100 and encases the various components thereof. The housing 112 may take any suitable form for electricity meters, and is generally configured to withstand a wide range of environmental conditions. The housing 112 thereby provides at least some protection against environmental conditions to the various elements disposed therein. Meter housings are well known in the art.

In this embodiment, each of the sensors 130, 132, 134, 136, 138, 140, 142, 144, 146, 148 and 152 is a sensor element and associated circuitry that is disposed “under the glass” or within the housing 112 in order to detect a select condition within the interior of the meter 100. The sensors include temperature sensors 130, 132, a humidity sensor 134, an antenna/EM sensor 136, a Hall effect sensor 138, a magnetic field sensor 140, an electric field sensor 142, an accelerometer 144, an electrostatic discharge sensor 146, a contaminant sensor 148, and an ultraviolet radiation sensor 152. In most cases, the sensor includes a sensing device that generates a signal that is dependent upon a condition. Each sensor is operably connected to provide information regarding the detected condition signal to the DPC 118b, typically through a unique input 118c.

As discussed above, the current coils 115 are conductors that pass the current from the power lines 102 to the feeder lines 106. The current coils 115 extend at least through the interior of the housing 112 to provide access to measurements of current and voltage delivered to the load 104 within the meter 100. The current coils 115 typically end in blades that connect to sockets, i.e. jaws, that form respective terminations of the power lines 102 and feeder lines 106 at the meter 100. Various configurations of current coils, sockets and meter blades are known in the art.

Voltage measurement devices or sensors 114 and current measurement devices or sensors 116 are secured within the housing 112. In general, the sensors 114, 116 are operably coupled to the current coils 115 to detect, respectively, voltage and current signals representative of voltage and current provided to the load 104, and to generate measurement signals therefrom. In particular, each of the voltage sensors 114 is configured to generate an analog voltage measurement signal having a waveform representative of the voltage provided to the load 104. Similarly, the each of the current sensors 116 is configured to generate an analog current measurement signal having a waveform representative of the current provided to the load 104. For purposes of example and explanation, FIG. 1 illustrates two voltage sensors 114 and current sensors 116 for generating measurement signals for residential 240-volt three wire single-phase electrical service. However, it will be intuitive to those skilled in the art that the principles of the present invention may also be applied to three-phase power systems.

In this embodiment, the voltage sensors 114 are configured to obtain a voltage measurement by direct contact with the current coil 115. The voltage sensor 114 (or the analog interface circuit 118a, discussed below) may include a voltage divider circuit to bring the measured voltage waveform to a magnitude that is suitable for a standard A/D converter. The voltage sensors 114 may alternatively take other known forms. Also in this embodiment, the current sensors 116 comprise toroid current transformers, which are inductively coupled to the current coils 115. The use of such devices for current measurement is well known.

The processing circuit 118 is a circuit that is operable to receive the analog measurement signals from the voltage sensors 114 and the current sensors 116 and generate energy consumption data therefrom. According to an exemplary embodiment, the processing circuit 118 includes analog interface circuitry 118a that receives and digitizes the measurement signals (and thus typically contains an A/D converter), and digital processing circuitry 118b that processes the digitized measurement signals to thereby generate the energy consumption data. Such circuits are well known in the art.

In one embodiment, the digital measurement signals consist of sampled voltage measurement waveforms and sampled current waveforms. To obtain such digital measurement signals, the analog interface circuit 118a samples the voltage measurement signals received from two voltage sensors 114 to generate two respective digital voltage signals VSA and VSB, and also samples the current measurement signals received from the current transformers 116 to generate two respective digital current signals ISA and ISB. Each of the signals VSA and VSB consists of a series of samples that is representative of the voltage waveform on one of the two power lines 102, after being scaled. Each of the signals ISA and ISB consists of a series of samples that is representative of the current waveform on one of the two power lines 102.

In some embodiments, the analog interface circuit 118a samples the voltage measurement signals received from two voltage sensors 114 to generate a single digital voltage signal VSAB which is representative of the voltage differential between the two power lines 102. In such embodiments, the individual power line digital waveforms VSA and VSB may be determined using 1/2 VSAB.

The use of digital current and voltage signals such as VSA, VSB, ISA and ISB to generate various metering information is well known in the art. By way of example, the digital processing circuitry 118b may, for electrical line phase, multiple contemporaneous current samples and voltage samples (e.g. VSA(n)*ISA(n) and VSB(n)*ISB(n)), and sum the resulting products, to generate a value representative of energy consumption (watt-hours). Such methods and variants thereof are well known. In other examples, the digital processing circuit 118b may generate RMS current and voltage values by averaging squares of the respective current and voltage values.

Moreover, the use of digital sampling of measured current and voltage allows for various additional measurements.

As is known in the art, the processing circuit 118 may include one or more integrated circuits, and may include a microcontroller, microprocessor, digital signal processor, or any combination thereof. One common architecture of the digital processing circuitry 118b used in electricity meters includes a digital signal processor and another microprocessor or microcontroller.

In addition to the above described operations relating to performing metering calculations, the processing circuit 118 also forms part of an arrangement for sensing, recording and communicating stress condition information regarding the meter 100. It will be appreciated, however, that the processing operations relating to stress condition sensing, recording and communicating may alternatively be performed in full, or in part, by a separate processing device that is not also responsible for metering calculations.

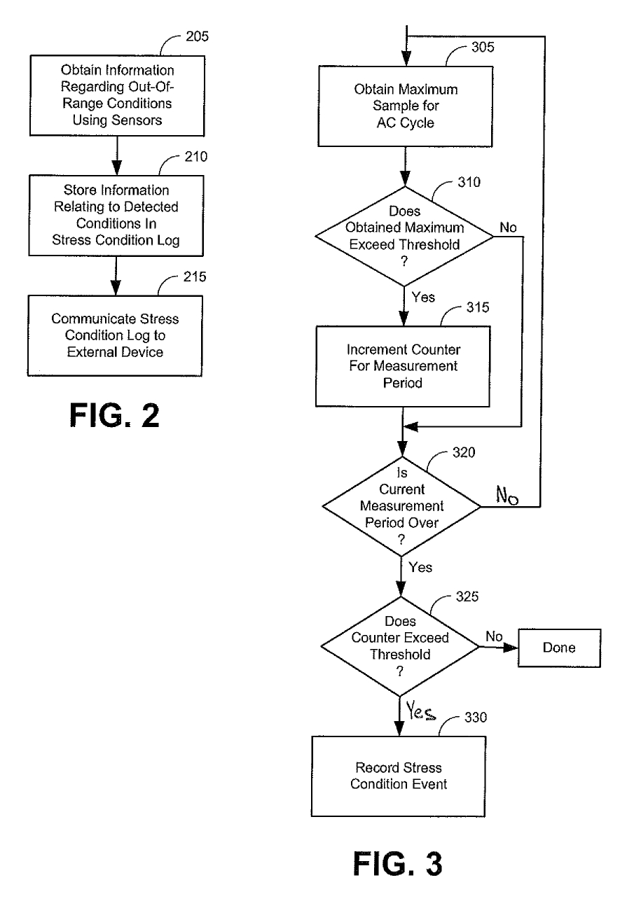

In this embodiment, however, the DPC 118b performs metering calculations as well as the logging of stress conditions detected within the meter 100. To this end, the DPC 118b has a plurality of inputs 118c operably coupled to receive information representative of various measurements for the sensors 130, 132, 134, 136, 138, 140, 142, 144, 146, 148 and 152. In general, the DPC 118b is configured to carry out the operations of FIG. 2 to effectuate stress condition logging.

In particular, the DPC 118b in step 205 cooperates with the sensors 130, 132, 134, 136, 138, 140, 142, 144, 146, 148 and 152 and/or the voltage and current sensors 114, 116 to detect and identify any out-of-range conditions to which the meter 100 is exposed. In step 210, the DPC 118b is also configured to store in the memory 119 information identifying detected out-of-range conditions based on the received measurements from the sensors 130, 132, 134, 136, 138, 140, 142, 144, 146, 148 and 152 and based on voltage and current measurements received from the analog interface circuit 118a. This information, which can be in the form of a stress condition log, may consist merely of a count of each type of stress condition. In other words, the stress condition log may merely identify for each separate stress condition type, the number of times that type of stress condition has been detected. Alternatively, the stress condition log stored in the memory 119 may include a record for each of out-of-range event. The record may include the type of event, the duration of the event, and a time stamp of the event.

It will be appreciated generating a mere count of each of the stress conditions will provide a technician with a snapshot of the types of stress to which the meter 100 has been exposed. Such information may be used to distinguish merely malfunctioning meters with meters that exhibit problems due to repetitive exposure to stress conditions.

However, generating a log with date stamps and duration information further allow technicians to determine possible causes of stress events through comparisons stress condition logs for multiple meters. For example, if multiple meters in a multi-dwelling building exhibit a temperature condition that is out of range, all on the same day at approximately the same time, it can be deduced that the over temperature condition was caused by sources external to the meter, as opposed to overheating of circuitry within the meter.

Accordingly, while even relatively simple stress condition logs have significant utility, more detailed stress condition logs can provide extensive useful information. However, more detailed stress condition logs require more processing and storage. Those of ordinary skill in the art may readily determine how to balance the use of resources with the extent of information to be stored in the stress condition log.

In addition to storing the stress condition log information, the DPC 118b periodically causes in step 215 the communication circuit 122 to communicate information representative of the stress condition log to an external device 124. In one embodiment, for example, the processing circuit 118 causes the stress condition log in the memory 119 to be communicated to the external device 124 so that the memory 119 may be purged and re-used. The external device 124 may, in turn, be used to gather stress condition logs for a plurality of meters to, thus enabling analysis of geographical, manufacturing or other common sources of potential stress conditions.

The memory 119 includes one or more storage devices of different types. The memory 119 may include volatile or non-volatile RAM, EEPROM, and/or other readable and writeable memory devices. In this embodiment, the memory 119 is a non-volatile memory that stores a stress condition log. As discussed briefly above, the stress condition log may include a plurality of stored count values, each count value associated with a particular stress condition. Alternatively, the stress condition log may include a plurality of stress condition data records, each data record including a stress condition type, a duration and/or time stamp, and quantitive severity (e.g. peak value) information for each stress condition occurrence. Some stress condition logs will include different types of information for different types of stress conditions.

The communication circuit 122 is one or more devices, and supporting circuitry, that is operably coupled to the processing circuit 118, and is configured to communicate with an external device such as the external device 124. The communication circuit 122 may, for example, transmit signals to the external device 124 via a tangible communication link (e.g., cable, wire, fiber, etc.), or via a wireless communication link. The external device 124 may be local or remote. As discussed above, the communication circuit 122 is operable to transmit data representative of the temperature information data log stored in the memory 119 to the external device 124. Such information may be used for later diagnostics of a meter malfunction, or in routine diagnostics to determine the possible onset of an adverse condition of the meter 100.

The display 128 is operably coupled to the processing unit 118 and provides a visual display of information, such as information regarding the operation of the meter 100. For example, the display 128 may provide a visual display regarding the energy consumption measurement (or even stress condition log data) of the meter 100.

The meter 100 performs well-known operations to obtain and record energy consumption information using the sensors 114, 116 and the processing circuit 118. In addition, the meter 100 detects stress conditions, or out-of-range conditions that could produce stress to meter components, and records information indicative of the detected stress conditions in the memory 119.

In general, the stress condition detection operations can be divided into two groups. A first group uses measurements from sensors that are otherwise necessary for metering purposes, such as the voltage sensors 114 and the current sensors 116. Such operations can include detection of over-voltage or over-current stress conditions. Exposing the components to sustained and/or spike current and voltage conditions can degrade components. A second group of stress condition detection operations uses measurements from sensors that have been added to the meter to measure a specific parameter, including the sensors 130, 132, 134, 136, 138, 140, 142, 144, 146, 148 and 152. The second group of stress condition detection operations detect conditions within the meter 100 that multiple components are exposed to, or in other words, environmental conditions. These environmental conditions include temperature, humidity, light, various electric, magnetic, electromagnetic fields, etc.

Details regarding several examples of the detection of stress conditions (or out-of-range) conditions are provided below.

### Sustained Over-Voltage Condition

A sustained over-voltage condition occurs if an over-voltage is sustained for multiple cycles or multiple seconds. For example, if the nominal line voltage is 120 Vrms, then a voltage of 130 132 Vrms that is sustained over several seconds or minutes may suitably be a stress condition that is useful to track. The sustained over-voltage condition can be determined without the use of a dedicated sensor because the required sensing operations are carried out by the voltage sensors 114 and the analog interface circuit 118a.

In one embodiment, the digital processing circuitry 118b uses the digital voltage samples VSA, VSB of the digital voltage signal (generated by the analog interface circuit 118a) to perform this operation. In particular, the DPC 118b counts the number of digital voltage samples that exceed a predetermined maximum (e.g. a maximum that corresponds to 125 132 Vrms) over a period of several cycles, several seconds or several minutes. If the number of samples exceeding the maximum during this selected “measurement period” exceeds a predetermined number, then a sustained over-voltage may be recorded.

FIG. 3 shows an exemplary set of operations that may be carried out by the DPC 118b to detect a sustained over-voltage condition, and to record relevant information pertaining to a detected sustained over-voltage condition. In step 305, the DPC 118b determines each maximum sample from each AC cycle. Such information may suitably be determined using the VSA, VSB digital waveform samples. In step 310, the DPC 118b determines if the maximum sample exceeds the predetermined threshold for an over-voltage. The threshold may suitably be, for example, 115% of the rated voltage. If so, then the DPC 118b proceeds to step 315. If not, then the DPC 118 proceeds to step 320.

Then, in step 315, the DPC 118b increments a counter for a current measurement period. In step 320, the DPC 118b determines whether the current measurement period is over. If not, then the DPC 118b returns to step 305. If so, then the DPC 118b proceeds to step 325.

In step 325, the measurement period has been completed. As a result, the DPC 118b determines whether a predetermined number of maximum samples exceeded the threshold during the measurement period in order to determine whether a sustained over-voltage condition exists. For example, the DPC 118b may determine whether 95% of the maximum samples in a 10 second period exceed the threshold. Other suitable methods and measurement periods may be used. For example, to eliminate processing when no over voltage is present, it can be advantageous to only begin a “measurement period” upon initial detection of an over-voltage in step 310.

In any event, if the answer in step 325 is positive, and thus it is determined that a sustained over-voltage has been detected, then the DPC 118b in step 330 would record the duration of any such sustained over voltage, and may even store average voltage variance (i.e. how much the measured maximum voltage sample of each 60 Hz cycle exceeds the expected maximum) for each of a number of predetermined measurement periods during the over-voltage event. Time, date and type of the event may also be stored. All information may be recorded in the memory 119.

### Surge or Spike Over Voltage

As opposed to a sustained over-voltage, a voltage surge or a spike may be an instantaneous event that lasts from less than one cycle to a few cycles. A spike may result from a temporary arc or lightning strike, among other things. The DPC 118b may detect such a spike or a surge by comparing voltage samples to either a single threshold, or a series of thresholds based on the 60 Hz waveform. For example, the DPC 118b can compare each waveform sample (or every 2^{nd}, 3^{rd}, etc. sample) to a corresponding sample in an ideal waveform pattern and determine whether the samples differ from the ideal by more than a threshold.

A first embodiment, however, employs a single threshold. This embodiment recognizes the fact that spikes and surges typically do not follow the 60 Hz cycle of the utility power, and typically exceed the nominal peak voltage of the AC waveform by a significant amount. In this embodiment, the DPC 118b determines whether a predetermined number of samples of the measured voltage, VSA and/or VSB, exceeds a threshold limit. To accommodate possible negative spikes, the DPC 118b may suitably include upper and lower limits. It is preferable that the limits significantly exceed the threshold for the sustained over-voltage detection, discussed above. It is also preferable that the number of samples in a row that must exceed the threshold be small, for example, those equivalent to less than 1/10th of a second.

Various other methods of determining a voltage surge or spike are known in the art and may be used. The DPC 118b may suitably record the time, date and duration of any such spike or surge, as well as information regarding the magnitude of the spike or surge. All information may be recorded in the memory 119.

### Sustained Over-Current Condition

This condition occurs if an over-current is sustained for multiple cycles or multiple seconds. An over-current is determined with reference to the maximum rating for the meter (or electrical service). For example, if the meter is rated as a 200 amp meter, then a current of 250 amps that is sustained over several seconds or minutes may suitably be a stress condition that is useful to track.

In one embodiment, the digital processing circuitry 118b uses the digital current samples of the digital current signal (generated by the analog interface circuit 118a) to perform this operation. In particular, the DPC 118b can suitably perform the steps of FIG. 3, discussed above, albeit with current samples as opposed to voltage samples. Thus, the DPC 118b may be programmed to count the maximum current samples from each 60 Hz cycle that exceed a predetermined threshold. In other words, the DPC 118b first determines each maximum sample from each AC cycle, and then determines if that maximum sample exceeds the predetermined threshold for an over-current. The DPC 118b then determines whether a predetermined number of maximum samples exceed the threshold during a measurement window. Other suitable methods may be used. For example, the DPC 118b may simply use the current samples ISA, ISB to determine if RMS current exceeds a predetermined threshold for a predetermined amount of time.

In any event, the DPC 118b would record the duration of any such sustained over current, and may even store average current variance (i.e. how much the measured maximum current sample of each 60 Hz cycle exceeds the expected maximum) for each of a number of predetermined measurement periods during the over-current event. Time and date of the event may also be stored. All information may be recorded in the memory 119.

### Surge or Spike Over Current

As opposed to a sustained over-current, a surge or a spike may be an instantaneous event that lasts from less than one cycle to a low number of cycles. A spike can be caused by a temporary arc or short circuit, among other things. The DPC 118b may detect such a spike or a surge by comparing current samples to a predetermined “spike” threshold, similar to the voltage spike detection operation, discussed above.

Various other methods of determining a current surge or spike are known in the art and may be used. The DPC 118b may suitably record the time, date and duration of any such spike or surge, as well as information regarding the magnitude of the spike or surge. All information may be recorded in the memory 119.

### General Condition Sensor Operations

At least some of the stress conditions relate to physical (e.g. environmental) conditions of the meter 100, as opposed stress conditions imposed by excessive voltage and current signals on the current path (e.g. the current coils 115 and meter blades). In general, these environmental conditions can be measured by the sensors 130, 132, 134, 136, 138, 140, 142, 144, 146, 148 and 152. The sensors 130, 132, 134, 136, 138, 140, 142, 144, 146, 148 and 152 are operably connected to corresponding inputs 118c of the DPC 118b. In some cases, the sensors 130, 132, 134, 136, 138, 140, 142, 144, 146, 148 and 152 are operably connected such that they DPC 118b only receives a signal when an out-of-range condition has been detected. In other cases, the sensors 130, 132, 134, 136, 138, 140, 142, 144, 146, 148 and 152 provide data to the DPC 118b, and the DPC 118b further processes the data to determine whether the data indicates an out-of-range condition.

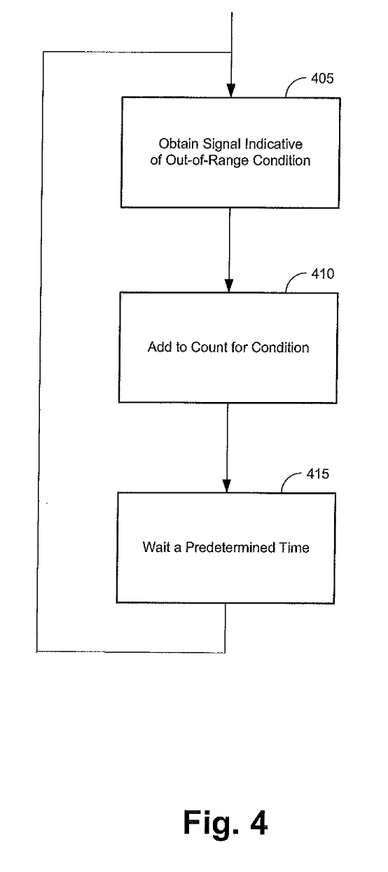

FIG. 4 shows the general operations of the processing circuit in detecting and storing out-of-range conditions that may be employed with at least some of the sensors 130, 132, 134, 136, 138, 140, 142, 144, 146, 148 and 152. The operations of FIG. 4 presume that any signal, for example, a logic state change at the input 118c, indicates that an out-of-range condition has been detected by the corresponding sensor. While variants of this process can be used for different stress condition sensors, the process of FIG. 4 provides at least a count of each stress condition as it occurs.

In step 405, the DPC 118b detects a signal received from a particular sensor indicating that the sensed condition is out of range and to be recorded. For example, the input 118c connected to the contaminant sensor 148 may see a change in logic state from a nominal value of “0” to a value of “1”. The sensor 148 in such a case only provides sufficient voltage to change the logic state of the input 118c when a stress condition exists. When the DPC 118b detects non-normal value, it is an indication that the stress condition exists.

In the operations of FIG. 4, the DPC 118b does not generally further process sensor signals to determine if they are out of range. Instead, in step 410, the DPC 118b adds to the count for the stress condition in question. For example, if the input connected to the humidity sensor 134 receives a signal, then the count for humidity stress conditions is incremented in the stress condition log, stored in the memory 119. In this example, it is assumed that the stress condition event log includes, for at least the sensors using the operations of FIG. 4, a count of each time the stress condition event is detected. If it is desired, then the DPC 118b can instead store a record in step 410, including a time stamp.

In step 415, the DPC 118b waits for a predetermined amount of time before returning to step 405. The predetermined wait is intended to insure that the same event does not cause a very sharp rise in the count of stress conditions. The predetermined wait may suitably be on the order of a minute, or several minutes, depending on the condition in question. It is acceptable for the same stress condition to be counted more than once for a single event, so long as there is a time interval between increments. Such information provides useful information as to the overall amount of stress that the meter 100 has experienced. In other embodiment, the wait interval is based on the calendar day, such that the stress condition log represents the number of days that a particular stress condition was present.

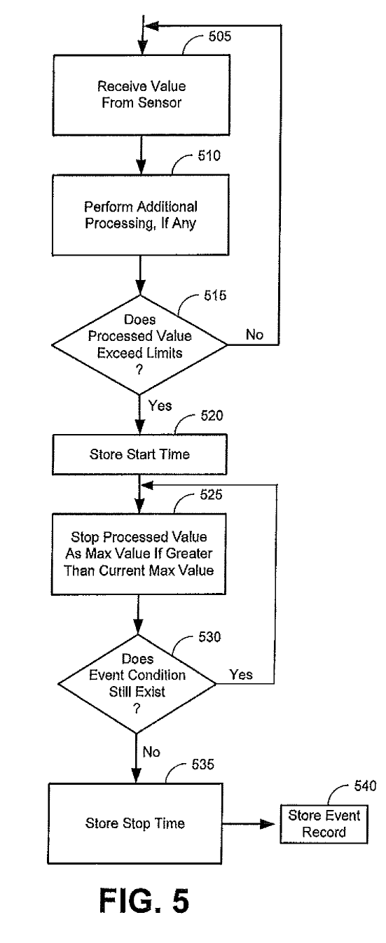

FIG. 5 shows another process that may be used to detect stress conditions using sensor information. The operations of FIG. 5 may be carried out when the DPC 118b must further process input data from sensors to determine if a stress condition exists. The operations of FIG. 5 require more computational resources than those of FIG. 4, but can provide additional information such as peak values and event duration.

In step 505, the DPC 118b receives a value from the sensor circuit indicative of a sensed condition. For example, the DPC 118b may suitably receive a temperature value indicative of a current temperature measurement. In step 510, the DPC 118b provides any additional processing to the received value. For example, the DPC 118b may perform filtering, or generate a derivative value, integrate, or otherwise generate a processed value based on the received value, and possibly based on previously received values and other factors.

In step 515, the DPC 118b determines whether the processed value exceeds a predetermined threshold or otherwise falls outside of predetermined limits. If so, then the processing circuit proceeds to step 520. If not, then the DPC 118b returns to step 505.

In step 520, the DPC 118b stores the current clock value with the meter 100 as the start time for the event. In this exemplary embodiment, it will be assumed that a maximum value for the processed value is also tracked in stored. Accordingly, in step 525, the DPC 118b stores the processed value if the processed value is the maximum for the event. For example, when the event commences, the initial processed value used to identify the event in step 515 will constitute the first maximum processed value. However, as the event continues and step 525 is subsequently executed, step 525 will only store the maximum processed value that is received.

In step 530, the DPC 118b repeats steps 505, 510 and 515 to determine whether the event condition still exists. In other words, the DPC 118b receives another value, processes the value per step 510, and determines whether the processed value still exceeds a threshold. If not, then the event has completed and the DPC proceeds to step 535. If so, however, then the DPC 118b loops back to repeat step 525 again. In step 525, the DPC 118b will store the processed value if it exceeds the currently stored maximum processed value.

In step 535, the DPC 118b records a stop time from the meter clock, because the event has completed. The DPC 118b then proceeds to step 540. In step 540, the DPC 118b stores a record of the event in the stress condition log. The record may suitably include information indicative of the start time, the duration, the type of event (humidity, temperature, change in temperature etc.) and the maximum recorded value. It will be appreciated that statistics other than peak value may readily be tracked by suitable modification of the operations of FIG. 5.

The individual examples of stress conditions are discussed below.

### Temperature Outside of Specified Limits

Although meters are intended for use in relatively extreme conditions, it may still be useful to track when meters are exposed to extreme (but technically acceptable) temperatures. It is also useful to track when meters are exposed to temperatures outside of the accepted operating limits for the meter. The temperature measurements may be specific to a device, or just for the interior of the meter in general.

To this end, one or more temperature sensors 130, 132 may be disposed within the meter 100. These temperature sensors 130, 132 should be small enough to take up a relatively small amount of space within the meter housing 112. To this end, temperature sensors disposed on integrated circuit are commercially available. For example, diodes that have a different characteristic based on temperature may be employed as sensors. In any event, the sensor output may be digitized and provided to the DPC 118b. The DPC 118b is configured to detect when the measured temperature exceeds one or more thresholds, and tracks the duration that the measured temperature exceeds each of those thresholds. The date, time and duration of the temperature event is then stored in the memory 119. In such an embodiment, the DPC 118b may suitably execute the general instructions of FIG. 5.

### Current Coil Temperature Rise Outside of Limits

In addition to general temperature measurements, temperature sensors may be placed at one or more places within the meter 100, including on or near sensitive devices such as the current coils 115, analog interface circuitry 118a, or the DPC 118b. One stress condition that is useful to monitor is the temperature of the current coils 115. To this end, the temperature sensor 132 is disposed on or near at least one of the current coils 115. An unusually high current coil temperature can result from a poor connection of the current coil 115 to the power lines 102 and/or feeder lines 106.

In the case of current coils, however, the measured temperature will vary as a function of the line current flowing through the lines 102, 106. Thus, to determine whether the measured current coil temperature is outside of limits, the measured temperature on the current coil 115 is compared to an expected temperature correlated to the contemporaneous RMS current measured by the meter 100, which can be calculated by the DPC 118b. The expected temperature may further be adjusted for time of year, time of day, or some measurement of the ambient temperature away from the current coils 115.

The above operations may be carried out using the general operations of FIG. 5, discussed above.

In any event, if the current coil temperature is significantly higher than would be expected for the current flowing through the current sensor 116, then the DPC 118b records the event. As with the others, the date, time and duration of the event are stored in the memory 119.

### Excessive Rate of Change of Temperature

Another potential stress on the meter 100 can be an excessively fast temperature change. In some cases, an excessively fast temperature change can be evidence of another stressor within the meter 100. Accordingly, the DPC 118b may further use temperature measurements obtained from temperature sensors 130, 132 within the meter 100 (discussed above) to calculate the rate of change of temperature. To this end, the DPC 118b calculates a value representative of the first derivative (or average rate of change) of the measured temperature using ordinary digital processing operations. For example, if temperature measurements are taken periodically, the change of temperature as a function of time may readily be calculated. This operation corresponds to step 510 of FIG. 5. The DPC 118b then compares the rate of change of temperature with an expected threshold value to determine if the rate of change is outside of normal limits. This operation corresponds to step 515 of FIG. 5.

If an excessive rate of temperature change event is identified, then the DPC 118b then stores the time, date and duration of the event in the memory 119. Specifics regarding the calculated rate of change during the event may also be stored.

Excessive Humidity and/or Moisture

Similar to temperature, a humidity and/or moisture sensor 134 may be incorporated into the meter 100. The DPC 118b receives information representative of measured moisture and/or humidity and compares the measurements to stored limits. If an event is detected, then information regarding the time, date, duration and severity of the event are stored.

Possible humidity sensors could include either a resistive humidity sensor, a capacitive humidity sensor, or a thermal conductivity humidity sensor. A possible embodiment using a resistive humidity sensor would cause an AC current to flow through the sensor and then sense the magnitude of the AC current. The AC current could have a frequency of 60 Hz since 60 Hz is a readily available frequency in an electricity meter. The magnitude of the current could be determined by using the A/D converter in the analog interface circuitry 118a directly and digitally converting to an RMS value or digitally rectifying and then averaging etc. The exponential response of a resistive humidity sensor could easily be made linear using a digital algorithm. Such an embodiment may be carried out using the steps of FIG. 5.

Another embodiment would be to simply detect if a threshold was exceeded. The humidity sensor 134 is configured to only provide a detectable signal (logic high signal) to the DPC 118b when the magnitude of the AC current exceeds a set threshold. When the DPC 118b receives the logic high signal at the input corresponding to the humidity sensor, the DPC 118b records the event indicating that a set humidity threshold was exceeded. In this embodiment, an algorithm to linearize the exponential response of the resistive humidity sensor would not be needed since it would only be determined that a threshold was exceeded. This embodiment may be carried out using the steps of FIG. 4.

### Excessive Electromagnetic Fields

The presence of electromagnetic fields is expected within an electricity meter. However, excessive fields can stress devices within the meter. Accordingly, embodiments of the invention test for excessive fields. To this end, an antenna 136 (such as a trace on a circuit board or some other conductor) is provided within the meter. The antenna picks up radiated voltage. The meter 100 also includes rectification circuit 137 that provides a rectified DC voltage that corresponds to the radiated voltage picked up the antenna 136. The rectified DC voltage is correlated to electromagnetic field.

The DPC 118b compares a value representative of the rectified DC voltage with a predetermine threshold. If the value exceeds the threshold, then the DPC 118b records a high electromagnetic field event by storing time, date, duration and severity information in the memory 119. However, it will be appreciated that the DPC 118b may also simply implement a count for electromagnetic field detection if the value exceeds the threshold.

### Excessive DC Magnetic Fields

Excessive magnetic fields present within the meter constitute a stress event. Accordingly, embodiments of the invention test for excessive fields. To this end, a sensor 138 including Hall sensor or reed switch may be provided within the meter 100. The sensor is operably coupled to the DPC 118b. In one embodiment, the reed switch may be configured (i.e. tuned) to trigger (turn on) when the sensed magnetic field exceeds a predetermined threshold.

In such a case, the DPC 118b receives a signal that the reed switch has closed, and records a high DC magnetic field event in the memory 119. These operations correspond to the operations of FIG. 4, discussed above.

### Other Stress Measurements

The magnetic field sensor 140 is configured to detect excessive line frequency magnetic fields (i.e. fields specifically correlated to the power line frequency). To this end, the magnetic sensor 140 includes an inductor that is operably connected to the DPC 118b. The induced 60 Hz magnetic field will cause the inductor to exhibit a detectable voltage and/or current characteristic. If this detectable voltage/current exceeds a threshold, then it is indicative of a magnetic field event that should be recorded. The magnetic field sensor 140 and the DPC 118b are configured to carry out the operations of FIG. 4 or 5 to record any such detected magnetic field event.

The electric field sensor 142 is configured to detect excessive electric fields within the meter 110. To this end, the electric field sensor 142 may suitably include a capacitor attached to the processing circuit 118. A significant electric field will cause the capacitor to exhibit a detectable voltage and/or current characteristic. If this detectable voltage/current exceeds a threshold, then it is indicative of an electric field event that should be recorded. The electric field sensor 142 and the DPC 118b are configured to carry out the operations of FIG. 4 or 5 to record any such detected electric field event.

The accelerometer sensor 144 is provided to detect excessive mechanical shock or vibration. The accelerometer is operably connected to the DPC 118b. Solid state (i.e. chip-based) accelerometers are known. The DPC 118b determines whether the accelerometer output indicates vibration or excessive shock using digital processing methods. If so, then the DPC 118b records an excessive shock and/or vibration event. Thus, the DPC 118b typically carries out the steps of FIG. 5 for detecting shock and vibration events.

To detect when the power line frequency is outside of limits, the DPC 118b may suitably use a zero crossing detector, which is often integral to the DPC 118b and the analog interface circuit 118a. The DPC 118b counts the number of detected “zero crossings” in the digital voltage signal over a predetermined period. Because a 60 Hz frequency translates to 120 zero crossings per second, the DPC 118b may readily determine whether the detected line frequency is at 60 Hz by determining whether the detected zero crossings are occurring at a rate of 120 per second. If the detected line frequency varies from 60 Hz by a predetermined amount for a predetermined amount of time, then the DPC 118b records an event.

The electrostatic discharge sensor 146 is provided to detect excessive electrostatic discharges. The electrostatic discharge sensor 146 includes a high impedance peak sensing circuit may be operably couple to the DPC 118b. High electrostatic discharges will be detected by the high impedance circuit. If the output of the high impedance peak sensing circuit exceeds a threshold, then the DPC 118b records an event, as per FIG. 4.

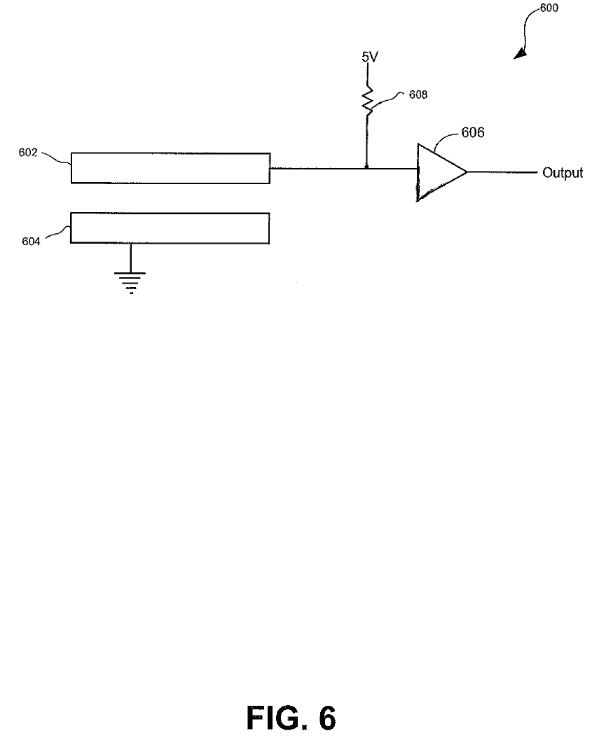

The contaminant sensor 148 is a circuit configured to detect excessive contaminants within the meter 100. To this end, a conduction circuit 600 such as that shown in FIG. 6 may be used. The conduction circuit 600 includes two conductors (plates, tubes, strips or rods) 602, 604 spaced apart from each other. One conductor 602 is connected to ground and the other conductor 604 is connected to an FET amplifier 606. A five volt source is also connected to the FET amplifier 606 via a high impedance resistor 608 (e.g. 100 M-ohm). The output of the FET amplifier 606 may suitably be connected to the DPC 118b.

In operation, contaminants will cause the conduction between the conductors 602, 604, thereby pulling the voltage at the FET amplifier 606 down. If sufficient contaminants are detected, it will cause a change of state in the output of the FET amplifier 606. The processing circuit 118b detects the change of state and records a contaminant stress event. The processing circuit 118b may suitably store the date, time and duration of the event in the memory 119.

The UV sensor 152 may suitably include a UV optical diode that is operably attached to the DPC 118b. The UV optical diode must also have an optical exposure to the exterior of the meter 100. In some cases, the communication circuit 122 of the meter 100 will have a UV optical diode that may be used for UV radiation detection. In such a case, the UV detection can be carried out by this diode, but only when communications are not being effectuated. In any event, the processing circuit 118 determines whether the UV optical diode output indicates the presence of excessive UV levels. If so, then the DPC 118b records an excessive UV level event.

In other embodiments of meters, additional components can be the source of additional stress conditions that can be tracked or logged. For example, many meters include service disconnect switches. Service disconnect switches are devices that controllably disconnect the source from the load within the meter 100. Service disconnect switches can be used to carry out pre-paid electrical service, for example. In such meters, another stress event that can be tracked is an excessive number of operations of the disconnect switches. The disconnect switches are typically relay switches capable of switching a large amount of power. Thus, excessive operation of the disconnect switches can stress circuits within the meter 100, and mostly the switches themselves.

In such meters, the DPC 118b may readily be configured to track the opening and closings of these switches. If the frequency of the switch operation exceeds a predetermined limit (i.e. switch state changes per hour, per day or per week), then the DPC 118b records an excessive switch operation.

It is also a stress event when the disconnect switches are opened under conditions of high current. While such event may or may not be part of normal operation, it can be useful to track the number of times the switches are opened under high current conditions. The DPC 118b may readily detect these events by detecting the opening of the switch and obtaining the most recent Irms calculated from the digital current samples.

It may be useful also to track excessive power failures to which the meter 100 is exposed. Excessive power fails (interruption of power on lines 102) be detected and recorded in a manner similar to that described above for excessive disconnect switch operation.

It will be appreciated that other ways of measuring the above described conditions or events may be employed. It will be appreciated that at least some of the advantages described herein may be obtained by detecting and logging less than all of the events discussed above.

We claim:

1. An arrangement, comprising:
a utility meter housing;
a first sensor disposed within the utility meter housing, the first sensor configured to measure a first parameter, the first parameter relating to an environmental condition within the meter housing;
a second sensor disposed within the utility meter housing, the second sensor configured to measure a second parameter;
a processing circuit disposed within the utility meter housing and operably connected to the first sensor and to the second sensor, the processing circuit configured to record information relating to one or more events, each event corresponding to a detection of an out of range condition by each of the first sensor and the second sensor.

2. The arrangement of claim 1, wherein the second sensor is a sensor employed for measuring electricity consumption.

3. The arrangement of claim 1, wherein the first sensor is a sensor configured to measure at least one of the group consisting of: temperature, humidity, DC magnetic field, electric field, electromagnetic waves, ultraviolet radiation, and vibration.

4. The arrangement of claim 1, further comprising a plurality of condition sensors disposed within the utility meter housing, each of the conditioned sensors configured to measure a parameter relating to a condition within the meter housing, wherein the processing circuit is further configured to record information relating events corresponding to a detection of an out of range condition by each of the plurality of condition sensors.

5. The arrangement of claim 4, wherein each of the plurality of condition sensors is configured to measure at least one of the group consisting of: temperature, humidity, DC magnetic field, electric field, electromagnetic waves, ultraviolet radiation, and vibration.

6. The arrangement of claim 1, further comprising a communication circuit operably coupled to transmit the recorded information relating to one or more events to an external device.

7. The arrangement of claim 6, wherein the second sensor is a sensor employed for measuring electricity consumption.

8. The arrangement of claim 7, further comprising a plurality of condition sensors disposed within the utility meter housing, each of the conditioned sensors configured to measure a parameter relating to a condition within the meter housing, wherein the processing circuit is further configured to record information relating events corresponding to a detection of an out of range condition by each of the plurality of condition sensors.

9. The arrangement of claim 8, wherein each of the plurality of condition sensors is configured to measure at least one of the group consisting of: temperature, humidity, DC magnetic field, electric field, electromagnetic waves, ultraviolet radiation, and vibration.

10. An arrangement, comprising:
a utility meter housing;
at least one voltage sensor disposed within the utility meter housing;
at least one current sensor disposed within the utility meter housing;
a first sensor disposed within the utility meter housing, the first sensor configured to measure a first parameter, the first parameter relating to a first condition within the meter housing;
a second sensor disposed within the utility meter housing, the second sensor configured to measure a second parameter relating to a second condition within the meter housing, wherein the second condition is distinct from the first condition;
a processing circuit disposed within the utility meter housing and operably connected to the first sensor and to the second sensor, the processing circuit configured to record information relating to one or more events, each event corresponding to a detection of an out of range condition by each of the first sensor and the second sensor.

11. The arrangement of claim 10, wherein the processing circuit is operably coupled to obtain voltage measurements from the voltage sensor, and is further configured to
determine if the voltage measurements indicate at least one stress condition; and
record information relating to the at least one stress condition if the voltage measurements indicate at least one stress condition.

12. The arrangement of claim 11, wherein the processing circuit is further configured to determine if the voltage measurements indicate at least one stress condition by:
determining if multiple values representative of approximate cyclical peaks in the voltage measurements exceed a threshold.

13. The arrangement of claim 11, wherein the processing circuit is further configured to determine if the voltage measurements indicate at least one stress condition by:
determining if values in the voltage measurements corresponding to voltage waveform samples exceed expected values.

14. The arrangement of claim 11, wherein the processing circuit is operably coupled to obtain current measurements from the current sensor, and is further configured to
determine if the current measurements indicate at least one stress condition; and
record information relating to the at least one stress condition if the current measurements indicate at least one stress condition.

15. The arrangement of claim 14, wherein the first sensor is a sensor configured to measure at least one of the group consisting of: temperature, humidity, DC magnetic field, electric field, electromagnetic waves, ultraviolet radiation, and vibration.

16. The arrangement of claim 15, wherein the first sensor comprises a DC magnetic field sensor including a Hall-effect switch operably coupled to the processing circuit, the Hall-effect switch configured to actuate in the presence of a select magnetic field, and wherein the processor configured to record first information relating to a first event responsive to the actuation of the Hall-effect switch.

17. The arrangement of claim 16, wherein the second sensor comprises an electromagnetic field sensor including an antenna device and a rectifying circuit operably coupled to the processing circuit, the antenna configured to detect radiated electromagnetic fields and the rectifying circuit configured to generate a rectified DC voltage representative of a magnitude of the electromagnetic fields, and wherein the processor configured to record first information relating to a first event responsive to the rectified DC voltage exceeding a threshold.

18. The arrangement of claim 17, wherein the first sensor comprises an accelerometer operably couple to the processing circuit, and wherein the processing circuit is configured to record third information relating to a third event responsive to when the accelerometer output exceeds a predefined threshold.
